(19) United States
(12) Patent Application Publication
(10) Pub. No.: US 2025/0295232 A1
(43) Pub. Date: Sep. 25, 2025

(54) ASSEMBLY COMPRISING A FIXED FURNITURE PART, A MOVING FURNITURE PART, A GUIDE DEVICE AND AN ELECTRICAL DRIVE DEVICE

(71) Applicant: Julius Blum GmbH, Hoechst (AT)

(72) Inventors: Alexander PETERLUNGER, Lustenau (AT); Bjoern Gasser, Mellau (AT)

(21) Appl. No.: 19/231,046

(22) Filed: Jun. 6, 2025

Related U.S. Application Data
(63) Continuation of application No. PCT/AT2023/060419, filed on Dec. 1, 2023.

(30) Foreign Application Priority Data
Dec. 23, 2022 (AT) A 50996/2022

(51) Int. Cl. A47B 88/457; A47B 88/46; A47B 88/473; A47B 88/483; A47B 88/919

(52) U.S. Cl. CPC A47B 88/457; A47B 88/46; A47B 88/473; A47B 88/483; A47B 88/919

(57) ABSTRACT

An assembly includes a fixed furniture part, a furniture part movable relative to the fixed furniture part, a guide device for guiding the moving furniture part relative to the fixed furniture part, with a carcass rail and a drawer rail that can be moved relative to the carcass rail. An electric drive device allows for at least partial automated movement of the moving furniture part relative to the fixed furniture part, and includes an electric motor. A closing device for the moving furniture part is provided, and a toothed rack is operatively connected to the electric drive device. The closing device is arranged on the drawer rail, and the toothed rack is arranged on the drawer rail. The toothed rack is detachably arranged on a support unit, and/or the support unit is detachably arranged on the closing device.

The present application is a continuation of International Application PCT/AT2023/060419 filed on Dec. 1, 2023. Thus, all of the subject matter of International Application PCT/AT2023/060419 is incorporated herein by reference.

### BACKGROUND OF THE INVENTION

The invention relates to an assembly comprising a fixed furniture part, in particular a furniture body, a furniture part, in particular a drawer, which is movable relative to the fixed furniture part, a guide device, in particular a drawer pull-out guide, for guiding the movable furniture part relative to the fixed furniture part, with at least one body rail and at least one drawer rail which is displaceable relative to the at least one body rail, and at least one electric drive device for the at least partially automated movement of the movable furniture part relative to the fixed furniture part, comprising an electric motor, in particular one which can be supplied with 230 V.

An assembly with a movable furniture part is already known from document EP 1 323 364 A1, in which a drawer is moved by means of a drive unit controlled by a triggering device. The triggering device comprises two manually operated push buttons—for example a drag switch—arranged on the drawer for three different switching states. The triggering device can be initiated according to the relative position of furniture part components or by tapping a furniture part component to generate a switching pulse.

An assembly with a movable furniture part is also already known from document EP 1 323 363 A1, in which a drive unit is controlled by a control device and a force measuring device in order to automatically support a movement desired by the user of a drawer in a bidirectional manner. In addition, a position measuring device may be provided which generates a position signal by means of which a current actual position, actual speed and actual acceleration can be calculated according to the measured position. Target values can also be determined so that essentially the same amount of force can be generated with varying drawer loads.

An assembly with a movable furniture part is also already known from document EP 2 642 899 A1, in which two sensors can generate different trigger sensitivities when force is exerted on a drawer.

A disadvantage of the prior art is that an overload clutch must be integrated into the drive device in order to compensate for proper functionality of the drive device in the event of vibrations or strong forces acting on the movable furniture part.

### SUMMARY OF THE INVENTION

The object of the present invention is therefore to provide an assembly which is improved in comparison with the prior art, in which the disadvantages of the prior art are at least partially eliminated, and which is characterized in particular by particularly advantageous compensation of external forces acting on the assembly.

Therefore, according to the invention, at least one closing device for the movable furniture part and at least one toothed rack operatively connected to the at least one electric drive device are provided. The at least one closing device is arranged, preferably directly, on the at least one drawer rail, and the at least one toothed rack is arranged, preferably indirectly, on the at least one drawer rail. The at least one toothed rack is detachably arranged on at least one support device, and/or the at least one support device is detachably arranged on the at least one closing device.

This allows the detachable connection-in particular the double detachable connection-to constitute an overload clutch between the component parts involved, whereby an overload clutch of the electric drive unit can be dispensed with.

For example, a tolerance in the interaction between a gear wheel of the electric drive device and the toothed rack caused by increased load on the toothed rack (for example in the event of vibrations or improper forces acting on the movable furniture part) can prevent a complete decoupling between the electric drive device and the toothed rack-without losing the effect of an overload clutch. Thus, the position of the drawer rail relative to the body rail remains clearly determinable via the relative position between the toothed rack and the gear wheel.

Decoupling from the electric motor is not necessary and can be generated, for example, via a one-way clutch. A required reference run can be prevented, wherein the support device can act as a coupling device.

### BRIEF DESCRIPTION OF THE DRAWINGS

Further details and advantages of the present invention will be explained in more detail below with reference to the drawings, in which:

FIGS. 1a, 1b show a guide device of a furniture part driven by an electric drive device according to a preferred embodiment in a perspective view with an enlarged detailed representation in the area of the electric drive device,

FIGS. 2-4 show the guide device according to the embodiment of FIG. 1b in perspective view with enlarged detailed representations in the area of a connection of a toothed rack to a drawer rail,

FIG. 5 shows the guide device according to the embodiment of FIG. 1b in a top view with an enlarged detailed representation in the area of a coupling between the toothed rack and a gear wheel of the electric drive device,

FIG. 6 shows the guide device according to the embodiment of FIG. 1b in a bottom view with an enlarged detailed representation in the area of a connection of the electric drive device to a body rail,

FIGS. 7a, 7b show the electric drive device according to the embodiment of FIG. 1b with a support for coupling to the body rail in a top view and a perspective view,

FIGS. 8a, 8b show the electric drive device according to the embodiment of FIG. 1b with disassembled housing in two perspective views from a front side and a rear side,

FIGS. 9, 10 show a path measuring device of the electric drive device according to the embodiment of FIG. 1b in an exploded view and in a top view with an enlarged detailed representation in the area of position sensors,

FIGS. 11, 12 show the electric drive device according to FIG. 8a in perspective view with enlarged detailed representation in the area of a protective body in the housing for protecting a gear against abrasion from a belt as well as a belt drive with belt tensioners on both sides,

FIG. 13a, 13b show a gear assembly of the electric drive device according to the embodiment of FIG. 1b in two perspective views,

FIGS. 14a, 14b show a one-way clutch of the electric drive device according to the embodiment of FIG. 1b in a plan view and a perspective view,

FIG. 15 shows a guide device according to an additional preferred embodiment with an electric drive device arranged on one side in a perspective view, and

FIG. 16 shows a diagram illustrating a clear position measurement or absolute path measurement for a movable furniture part along a guide device by a path measuring device according to the embodiment of FIG. 9 via sensor angles over pull-out lengths.

### DETAILED DESCRIPTION OF THE INVENTION

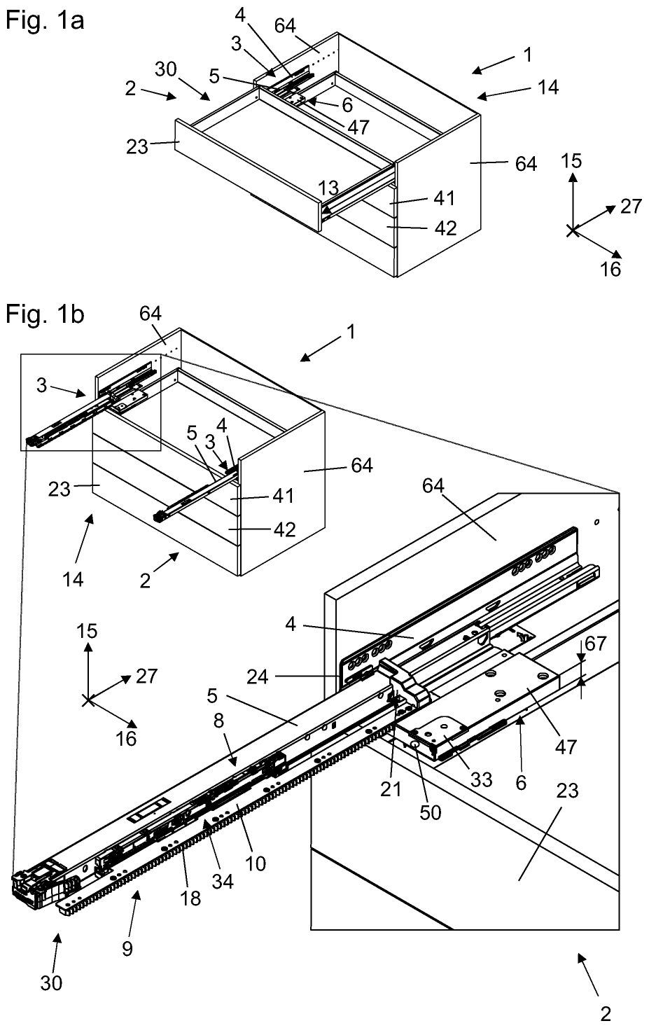

FIG. 1a shows a piece of furniture with movable furniture parts 2 in the form of drawers, which can be moved relative to a fixed furniture part 1 in the form of a furniture body via a guide device 3 in the form of a drawer pull-out guide by an electric drive device 6.

The movable furniture parts 2 can be divided into a first movable furniture part 41 and additional movable furniture parts 42, wherein the additional movable furniture parts 42 are arranged in the use position 14 of the assembly below the first movable furniture part 41.

However, the piece of furniture is not limited to drawers and can in general include other containers. For example, the piece of furniture can be a furniture body with a flap, a cabinet with a folding and/or sliding door or the like.

FIG. 1b shows the piece of furniture with a hidden movable furniture part 2 in an assembly comprising the fixed furniture part 1, the furniture part 2 movable relative to the fixed furniture part 1 and two guide devices 3 for guiding the movable furniture part 2 relative to the fixed furniture part 1.

The assembly comprises an electric drive device 6 for at least partially automated movement of the movable furniture part 2 relative to the fixed furniture part 1, comprising an electric motor 7 that can be supplied with 230 V. The energy supply for the electric motor 7 is in general arbitrary and can also be operated with different voltages. In general, a voltage may also be lower-particularly due to local or regional power grid characteristics-in order to supply the electric motor 7 with sufficient energy.

The guide devices 3 each comprise a body rail 4 arranged on the fixed furniture part 1 and a drawer rail 5 arranged on the movable furniture part 2. In general, a center rail can be arranged at least partially between the body rail 4 and the drawer rail 5, although this is in general not necessary—in particular for a full pullout of the movable furniture part 2 due to the front-side assembly of the electric drive device 6 and the connection to a toothed rack 9.

In the detailed section, the connection of the electric drive device 6 to the body rail 4 and a toothed rack 9 to the drawer rail 5 is shown enlarged, wherein the drawer rail 5 comprises a first intersection 34 (optionally a plurality of first intersections 34) which is suitable for fixing an ejection device 11 and a closing device 8 to the drawer rail 5.

At the first intersection 34, a closing device 8 is arranged, which is in general not required. Alternatively or additionally, an ejection device 11, in particular a mechanical or electrical one, can be arranged at the first intersection 34. Preferably, the ejection device 11 comprises a tip-on function with which an ejection process can be triggered by an overpressure movement.

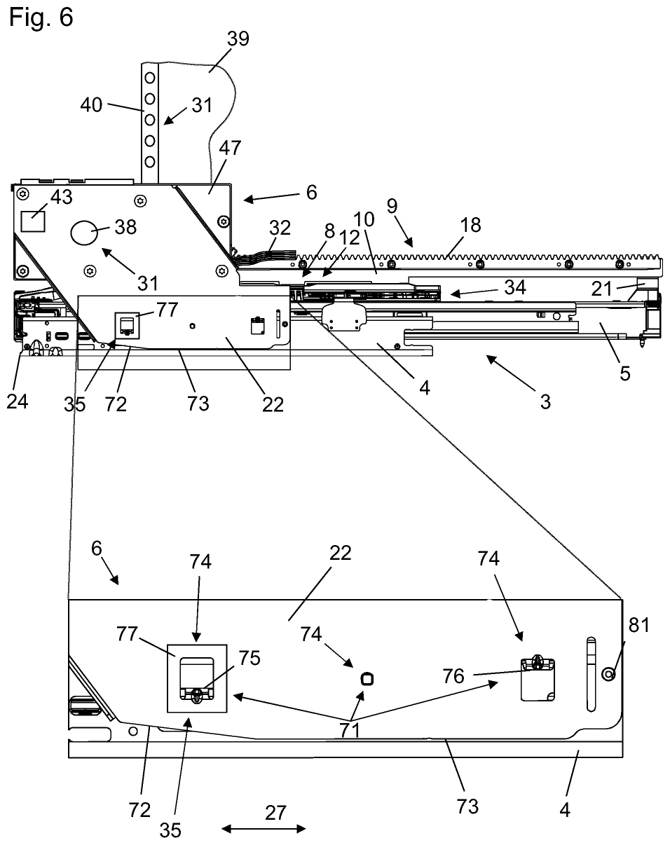

The body rail 4 comprises a second intersection 35 (optionally a plurality of second intersections 35) which is suitable for fixing a carrier 36 for the ejection device 11 or the closing device 8 to the body rail 4. The second intersection 35 is located (not visible in the view) on the underside of the body rail 4 (see FIG. 6).

The electric drive device 6 is arranged at the second intersection 35 and the toothed rack 9 for transmitting power from the electric drive device 6 to the drawer rail 5 is arranged at the first intersection 34.

The connection of the electric drive device 6 is made via a clip connection 71 and via a pivoting process for hanging (see FIG. 6). The connection of the toothed rack 9 is effected via a clip connection 71 during a translatory insertion process into the closing device 8 or the drawer rail 5. For example, the clip connection 71 (on the toothed rack 9, the closing device 8 or the drawer rail 5) can have a latchable web or a latching boss 81, wherein hooks 75 are in general also possible as an alternative or in addition. In the exemplary embodiment, the toothed rack 9 is connected to the closing device 8, which may optionally have an ejection device 11 or to which an ejection device 11 may optionally be connected (replacing the closing device 8 is also conceivable). A direct connection of the toothed rack 9 to the drawer rail 5 is also possible. An indirect connection of the electric drive device 8 (for example via a carrier 36 for the closing device 8) is also possible, although a direct connection is preferred.

The toothed rack 9 is to be designed so wide that equivalent means such as a belt (optionally with a toothing 18), a cable or the like for transmitting power between the electric drive device 6 and the drawer rail 5 are also included.

In the use position 14 of the assembly, the electric drive device 6 is arranged substantially completely below the movable furniture part 2 on the body rail 4, wherein, if necessary, a furniture part front 23 (for example for contacting a trigger sensor 59) can protrude in the vertical direction 15 below an upper side of the electric drive device 6 or the electric drive device 6. A base of the movable furniture part 2 is arranged completely above the electric drive device during the movement of the movable furniture part. The movable furniture part 2 moves over the electric drive device 6 during use.

The electric drive device 6 is arranged stationary on the body rail 4 and is in constant connection to the toothed rack 9 for movement transmission over an entire path 13 for the movable furniture part 2 along the guide device 3.

The movable furniture part 2 comprises a furniture part front 23, wherein the electric drive device 6 is arranged on the body rail 4 in the use position 14 of the assembly in the region of a free end 24 of the body rail 4 facing the furniture part front 23.

In the closed position, the electric drive device 6 is arranged flush with the drawer rail 5 or the toothed rack 9. The toothed rack 9 can compensate for any pull-out loss caused by the fastening of the body rail and/or by the use of a specific trigger sensor type.

The electric drive device 6 is arranged substantially flush with the free end 24 of the body rail 4 both in the closed position and in the open position 30.

The fixed furniture part 1 comprises two furniture panels 64 oriented vertically and parallel to one another in the use position 14, wherein exactly one electric drive device 6 is arranged stationary on one of the two furniture panels 64 indirectly via the body rail 4. In general, however, an additional electric drive device 6 or an additional toothed rack 9 can also be arranged on the opposite furniture panel 64, although this is not mandatory.

In the use position 14 of the assembly, the movable furniture part 2 comprises a furniture part front 23, wherein the electric drive device 6 is arranged on the body rail 4 in the region of a free end 24 of the body rail 4 facing the furniture part front 23 (essentially flush with the free end 24 or the drawer rail 5 in the closed position or the toothed rack 9 in the closed position).

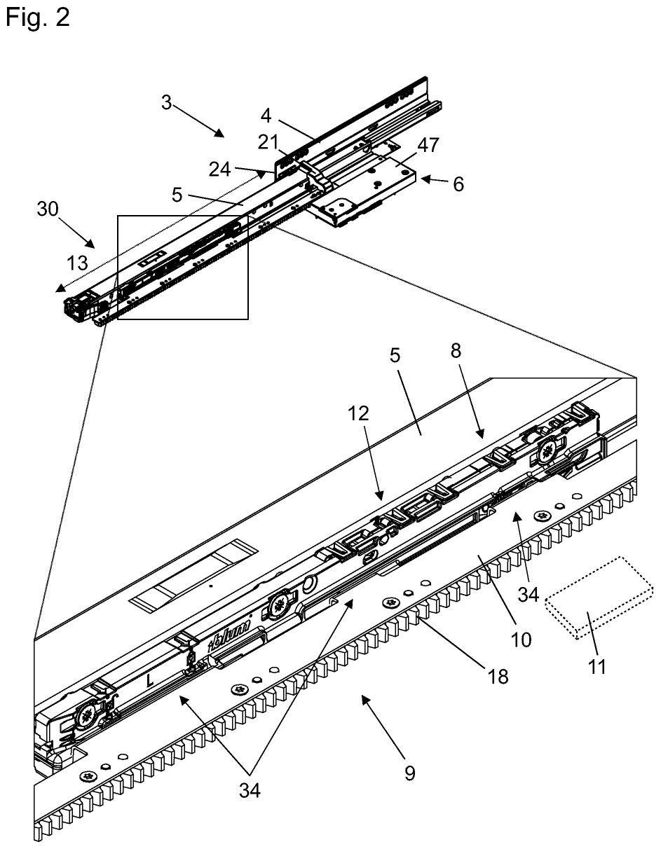

FIG. 2 shows the connection of the electric drive device 6 to the body rail 4 without surrounding furniture parts 1, 2, wherein the drawer rail 5 is fully extended over the path 13 as a pull-out path for the movable furniture part 2.

In the enlarged detail section, the connection of the toothed rack 9 to the drawer rail 5 or the closing device 8 is visible, with an ejection device 11 being indicated in dotted line, which can be arranged alternatively or additionally at the first intersection 34. It is also conceivable to provide a locking device 69 for inhibiting a movement of the movable furniture part 2 at the first intersection 34. A damping device 12 is integrated in the closing device 8, wherein the damping device 12 may also be provided as a separate component.

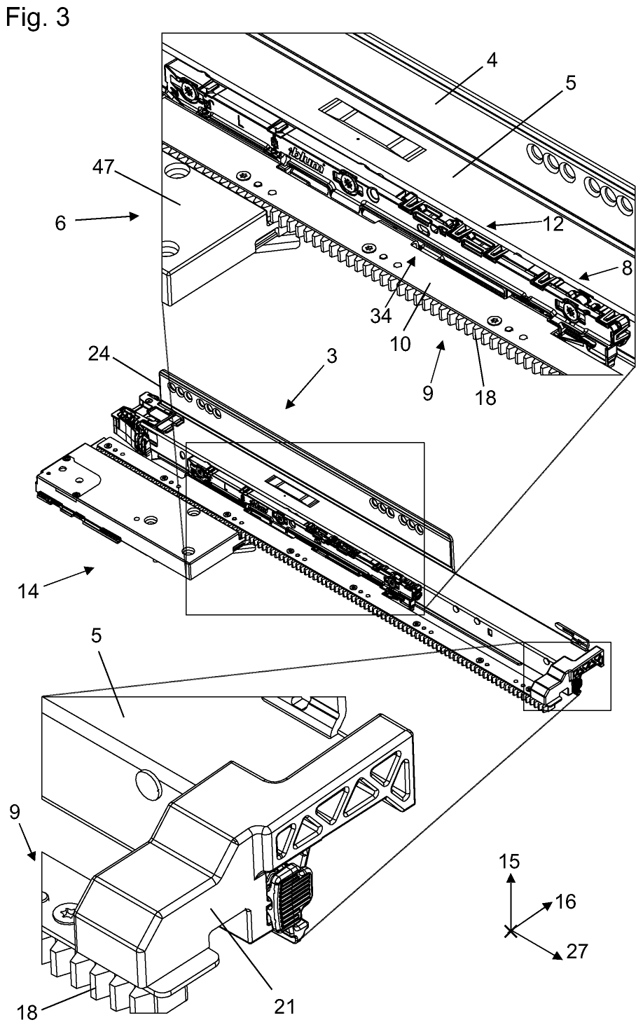

FIG. 3 shows the guide device 3 with the electric drive device 6 for the automated movement of the movable furniture part 2 or the drawer rail 5 with the electric motor 7 (which can be supplied with 230 V).

The closing device 8 for the movable furniture part 2 and the toothed rack 9 operatively connected to the electric drive device 6 are mounted, wherein the closing device 8 is arranged directly on the drawer rail 5 and the toothed rack 9 is arranged indirectly via the closing device 8 on the first intersection 34 of the drawer rail 5. In general, the toothed rack 9 can alternatively or additionally directly contact the drawer rail 5.

The toothed rack 9 is detachably arranged on a support device 10, and the support device 10 is detachably arranged on the closing device 8.

In this context, the detachable connection of the support device 10 means a connection that can be released without force, preferably without tools.

The support device 10 is arranged in the horizontal direction 16 between the toothed rack 9 and the closing device 8, although in general it is also possible to provide a toothed rack 9 pointing downwards in the vertical direction 15.

The support device 10 or the closing device 8 can comprise a mechanical or electrical ejection device 11, wherein a damping device 12 is provided in the closing device 8 for damping a movement of the movable furniture part 2 in a region of the closed position.

The stationary electric drive device 6 is in constant connection to the toothed rack 9 for transmitting movement over the entire path 13 along the guide device 3, wherein the electric drive device 6 comprises a gear wheel 17 meshing with the toothed rack 9 in connection with the electric motor 7.

The toothed rack 9 is arranged laterally between the electric drive device 6 and the drawer rail 5 over the entire path 13.

In this embodiment, exactly one electric drive device 6 is provided on one of the two body rails 4 of the guide devices 3, and exactly one toothed rack 9 is provided on one of the two drawer rails 5 of the guide devices 3, although in general it is also possible to use two electric drive devices 6 on both body rails 4.

A power supply to the electric drive device 6 or to any additional current sink present—such as the lighting means 31 in FIG. 6—is provided via the body rail 4, wherein the power supply can alternatively or additionally be provided via the toothed rack 9. The power supply can be routed between the two body rails 4 of the two provided guide devices 3 in order, for example, to supply energy to an additional trigger sensor 65. A separate power supply per body rail 4 (or toothed rack 9) is also possible.

A toothing 18 of the toothed rack 9 is oriented in the use position 14 of the assembly in the horizontal direction 16 in a direction pointing away from the drawer rail 5, although in general an orientation in the vertical direction 15 downwards is also possible.

The toothed rack 9 is coupled to the gear wheel 17 of the electric drive device 6, wherein the toothed rack 9 (via a connection to the support device 10 or by the connection of the support device 10) is mounted in the horizontal direction 16 relative to the drawer rail 5, so as to be bendable (or pivotable is also conceivable) and thus to be mounted for limited lateral movement. For example, the toothed rack 9 could also be mounted to be movable to a limited extent in the vertical direction 15 (away from the gear wheel 17) even with a vertical toothing 18. This enables a secure coupling with the elastic drive device 6, while also reducing assembly effort due to a reduced tendency to tilt and reducing noise generation due to elastic or flexible deformation. For example, the toothed rack 9 can be preloaded in the direction of the gear wheel 17 by a spring or by its own elasticity in order to ensure a positive connection to the electric drive device 6 during operation.

It is particularly preferable to design the toothed rack 9 to be flexible to ensure a safe, harmonious and continuous transmission of movement through elastic deformation.

This makes it possible for the detachable connection—in particular the double detachable connection—to constitute an overload clutch via the component parts involved, whereby an overload clutch 68 of the electric drive unit 6 can be dispensed with. For example, a tolerance in the interaction between the gear wheel 17 and the toothed rack 9 caused by increased load on the toothed rack 2 (for example in the event of vibrations or improper forces acting on the movable furniture part 2) can prevent a complete decoupling between the electric drive device 6 and the toothed rack 9—without losing the effect of an overload clutch, whereby the position of the drawer rail 5 relative to the body rail 4 remains clearly determinable via the relative position between the toothed rack 9 and the gear wheel 17. Decoupling from the electric motor 7 is not necessary and can be generated, for example, via a one-way clutch 29. A required reference run can be prevented, wherein the support device 10 can act as a coupling device.

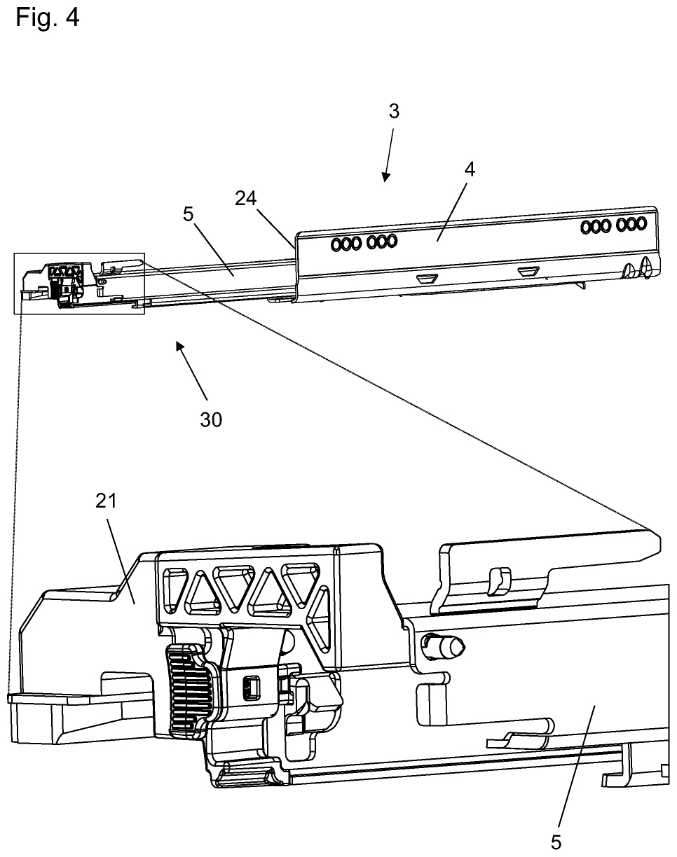

FIG. 4 shows the guide device 3 with an enlarged detail section of the drawer rail 5 in the area of a coupling device on the rear side of the furniture part for the movable furniture part 2.

The drawer rail 5 comprises a bearing device 21 for the toothed rack 9, wherein the bearing device 21 is arranged on the drawer rail 5 and on the toothed rack 9, wherein a support 22 of the electric drive device 6 for connecting the electric drive device 6 to the body rail 4 can be traversed by the toothed rack 9 and the bearing device 21 in the course of a relative movement between the drawer rail 5 and the body rail 4.

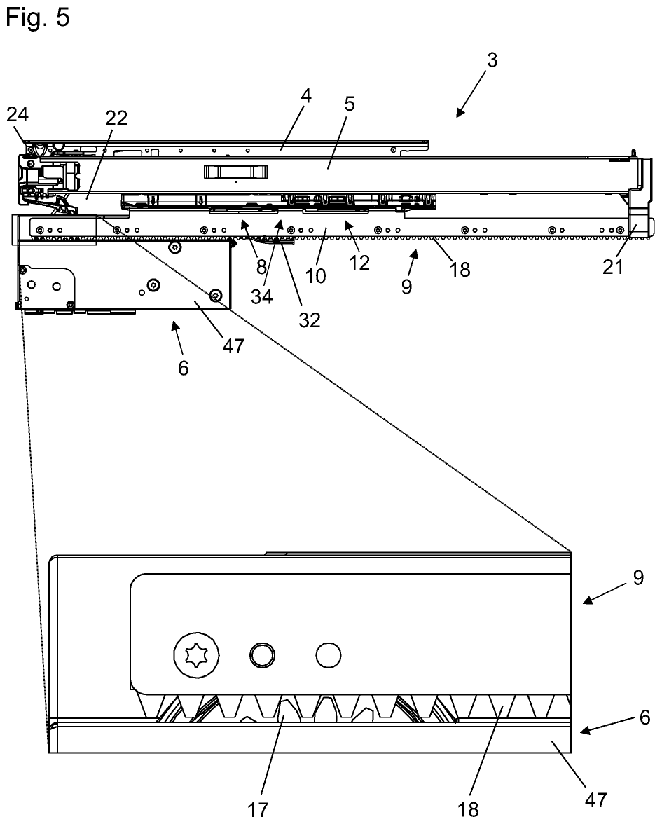

FIG. 5 shows the guide device 3, wherein the coupling between a gear wheel 17 of the electric drive device 6 in operative connection with the electric motor 7 and a toothing 18 of the toothed rack 9 is shown in an enlarged detail section.

The electric motor 7 (or the electric drive device 6) comprises a gear wheel 17 meshing with the toothed rack 9 inside the coupling with gear stages 55 of the electric drive device 6.

In the position of use 14 of the assembly, the gear wheel 17 is oriented in the horizontal direction 16 in the direction of the drawer rail 5, although is it also possible to provide a gear wheel 17 of the electric drive device 6 which is oriented upwards in the vertical direction 15.

The toothed rack 9 is arranged between the electric drive device 6 and the drawer rail 5. The guide device 3 is in the closed position, whereby a movable furniture part 2 arranged on the drawer rail 5 would be located in an end position.

In order to improve a degree of force transmission by the power transmitted via the electric drive device 6 to the movable furniture part with regard to a time and/or an intensity, the electric drive device is controlled by a microcontroller 37, which functions as a control and/or regulating device 44 and acts as a computing unit.

An exemplary computing unit-supported method for moving the movable furniture part 2 relative to the fixed furniture part 1 along the guide device 3 by the electric drive device 6 for at least partially automated movement of the movable furniture part 2 relative to the fixed furniture part 1 via an electric motor 17 can be implemented as follows: The microcontroller 37, comprising the computing unit and a memory unit connected to the computing unit, determines a model of the movable furniture part 2 according to at least one static data set stored in the memory unit, the movable furniture part 2 is moved manually from a partial or complete open position 30 and a closed position towards the closed position or vice versa, and the microcontroller 37 calculates a predicted movement trajectory of the movable furniture part 2 along the guide device 3 according to at least one dynamic data set.

The static data set can include, for example, a mass of the movable furniture part 2, a friction of the movable furniture part 2 on the guide device 3, a dimensioning of the movable furniture part 2, a load in the movable furniture part 2, a dimensioning of the guide device 3, a path 13 along the guide device 3, tolerance limits, etc.

The path 13 can in general be determined by a pull-out path for the movable furniture part 2 or a longitudinal extension of the toothed rack 9, via which at least a partial drive is effected by the electric drive device 6 via an automated control. A drive over path 13 is possible, although a drive over parts of path 13 is preferred.

The dynamic data set can, for example, include an absolute path traveled by the movable furniture part 2 relative to the stationary furniture part 1, a speed of the movable furniture part 2, a load in the movable furniture part 2, an acceleration profile of the movable furniture part 2 (in general determined via a speed measuring device 52), an acceleration path of the movable furniture part 2, a kinetic energy of the movable furniture part 2, etc.

The static data set or the dynamic data set can be determined in a reference run of the movable furniture part 2 or via a plurality of reference runs—possibly with varying loads of the movable furniture part 2. Alternatively or additionally, it is possible to store static data records in a storage unit without a reference run and to compare static data records or dynamic data records with data records stored in the storage unit or to correct them according to the stored data records.

The following aspects are provided for in this embodiment, but do not necessarily have to be implemented.

According to the predicted movement trajectory, the microcontroller 37 makes a decision as to whether the electric drive device 6 should apply force to the movable furniture part 2 or whether the movable furniture part 2 should be movable manually in a free-run area. The electric motor 7 comprises a one-way clutch 29, with which a power transmission from the electric motor 7 to the movable furniture part 2 is separated in the free-run area.

The microcontroller 37 calculates, according to the at least one static data set and the at least one dynamic data set, whether the movable furniture part 2 reaches the closed position without application of force via the electric drive device 6, wherein a speed of the movable furniture part 2 upon entry into the closed position is determined according to a damping power of a damping device 12 arranged on the movable furniture part 2 or the fixed furniture part 1.

According to the predicted movement trajectory, the microcontroller 37 defines a speed profile for the drive of the movable furniture part 2 mediated via the electric drive device 6, wherein the electric drive device 6 applies force to the movable furniture part 2 according to the speed profile. The speed profile is created according to the at least one static data set or the at least one dynamic data set, wherein the movable furniture part 2 is supplied with energy at a speed of the movable furniture part 2 below the speed profile and is braked by the electric drive device 6 at a speed of the movable furniture part 2 above the speed profile, and a force transmission to the movable furniture part 2 is initiated at a predefined speed threshold value or a predefined position threshold value.

The microcontroller 37 is equipped with a learning algorithm in the form of artificial intelligence comprising a neural network with machine learning or deep learning, wherein the learning algorithm analyzes and compares the predicted movement trajectories of a history. The history of predicted movement trajectories is used, according to the respective static data sets or dynamic data sets, for future movement trajectories to be predicted, future speed profiles or future decisions regarding the application of force to the movable furniture part 2.

Movement sequences of the movable furniture part 2 along a guide device 3 are used as training data for the artificial intelligence. It has proven particularly advantageous to use different guide devices 3 and varying force applications or loads of the movable furniture part 2 to train the learning algorithm. Movement sequences on the specific guide device and the specific movable furniture part 2 can be added to the training data for learning purposes—in particular continuously.

The electric drive device 6 remains stationary on the body rail 4 during movement of the movable furniture part 2 and is in constant connection with the toothed rack 9 arranged on the drawer rail 5.

The movable furniture part 2 can be driven via the drawer rail 5 starting from the open position 30 or a position between the open position 30 and the closed position over an entire path 13 up to the closed position and to the open position 30 or only over a partial area of the path 13 by the electric drive device 6, wherein an application of force by the electric drive device 6 starting from the closed position in the direction of the open position 30 is initiated by an overpressure movement of the movable furniture part 2 or via an exclusively electronic trigger sensor 59. The movable furniture part 2 can be moved manually in a non-driven section of the path 13 in a free-run area, so that no force is applied by the electric motor 7 to the movable furniture part 2.

Driven sections of the path 13 have proven to be particularly advantageous in the direction of the open position 30—in particular starting from the closed position—between 50 mm and 150 mm and in the direction of the closed position—in particular starting from the fully open position 30—between 5 mm and 20 mm.

A movement of the movable furniture part 2 in the direction of the closed position or the open position 30 can be damped, braked or blocked via the electric drive device 6, wherein the movable furniture part 2 is subjected to force in the direction of the closed position by a closing device 8 in the region of the closed position. However, a closing device 8 is not mandatory, and the closing device 8 can be replaced, for example, by the electric drive device 6.

An algorithm or a computer program product comprising instructions for executing the method can be stored in the microcontroller 37 or the control and/or regulating device 44, transmitted on a data carrier signal or stored on a—in particular non-volatile—data carrier.

The computing unit of the microcontroller 37 or of the control and/or regulating device 44 is configured to determine a model of the movable furniture part 2 according to the at least one static data set stored in the memory unit and to calculate a predicted movement trajectory of the movable furniture part 2 along the guide device 3 according to the at least one dynamic data set, possibly stored in the memory unit. The electric drive device 6 comprises the computing unit.

The storage unit has sufficient storage capacity to provide the information required for the model. The computing unit has sufficient computing power to calculate the model with the accuracy required for application in the furniture industry with respect to a speed profile to be transferred to the movable furniture part 2. The storage capacity and the computing power can be adjusted according to the desired precision of the model or the desired accuracy of an output parameter to be generated from the model, such as the velocity profile.

The speed profile preferably comprises an amplitude of the acceleration, a path of the acceleration, the path 13 or a portion of the path 13 over which the movable furniture part 2 is to be subjected to speed or is to be driven, a maximum speed and the like. As input parameters, for example, a current load of the movable furniture part 2 or a pulse transmission (discrete or continuous) from the operator of the movable furniture part 2 can be used as a dynamic parameter.

By means of the method, and in particular the microcontroller 37 or the control and/or regulating device 44, a support detection for a movement of the movable furniture part 2 can be generated, wherein the movable furniture part 2 can be driven in the closing direction or in the opening direction, for example, in such a way that the movable furniture part 2 is moved into an end position (closed position or open position 30) essentially silently and/or without significant force acting on the component parts. In general, a partial drive or a complete drive—in particular over the entire path 13—into the end position is possible.

Due to the increased functionality of the method compared to the prior art, undesirable disharmonious movement trajectories can be prevented—in particular with changing force applications and/or loads of the movable furniture part 2 or varying guide devices 3—wherein improperly high or low speeds of the movable furniture part 2 can be prevented, which do not allow movement into a desired end position of the movable furniture part 2 or can cause damage.

The microcontroller 37 can be understood as a control and/or regulating device 44 or can comprise such a computing unit.

FIG. 6 shows that the electric drive device 6 comprises a plurality of lighting means 31 which are stationary relative to the fixed furniture part 1, although in general it is also possible to provide only one lighting means 31. The lighting means 31 is arranged on the electric drive device 6.

A lighting means 31 is provided in the form of a lamp 38—designed as an LED lamp—and is integrated in the electric drive device 6 in some areas in the housing 47 of the electric drive device 6.

An additional lighting means 31 is provided in the form of a strip-like illuminant 40—designed as an LED strip—and is arranged directly on the electric drive device 6. The dotted line indicates that the additional lighting means 31 can also be in the form of a flat illuminant 39—herein provided as an LED surface. For example, the additional lighting means 31 can also be arranged indirectly on the electric drive device 6—for example by connecting a power line 32 (not shown for reasons of clarity) to the power line 32 of the electric drive device 6.

The lighting means 31 are oriented on an underside of the electric drive device 6 in such a way that the additional movable furniture parts 42 can be illuminated by the lighting means 31, wherein the lighting means 31 are arranged on the electric drive device 6 of the first movable furniture part 41. However, the lighting means 31 can in general be arranged alternatively or additionally on the electric drive device 6 or the power line 32 of the electric drive device 6 of the first movable furniture part 41 in such a way that the first movable furniture part 41 can be illuminated by the lighting means 31.

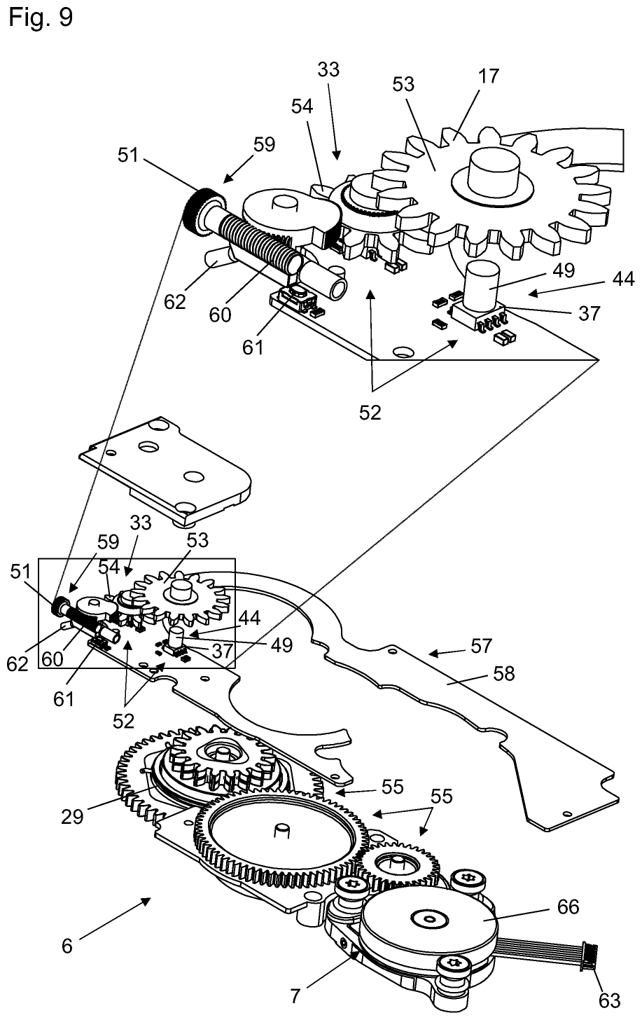

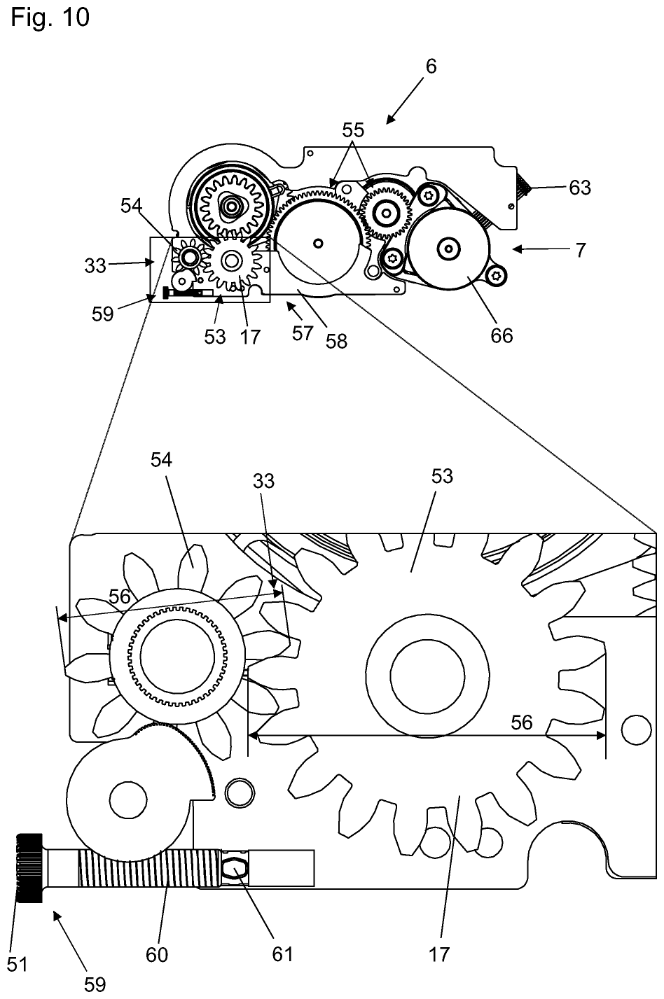

As explained in more detail in FIG. 9 and FIG. 10, a path measuring device 33 is provided, which can be used alternatively or in addition to the schematically indicated motion sensor 43 in order to detect a relative position—such as a complete or partial open position 30 of the movable furniture part 2 relative to the fixed furniture part 1. The lighting means 31 can be activated by a control and/or regulating device 44 or a microcontroller 37 according to the determined relative position. The path measuring device 33 and the motion sensor 43 are arranged on the electric drive device 6 and coupled to the power line 32 of the electric drive device 6 and the lighting means 31. In general, the distance sensor 50 (see FIG. 1b) can be used alternatively or in addition to the path measuring device 33 or the motion sensor 43 to determine the relative position for triggering the lighting means 31. The number of lighting means 31 is in general arbitrary.

The lighting means 31 are arranged between the two body rails 4 of the guide device 3, wherein the strip-like illuminant 40 is located laterally between the body rails 4 and extends completely linearly between the two body rails 4.

There is a direct power connection between the two body rails 4, which can be used to illuminate the movable furniture part 2, wherein the power connection or the power supply is routed via at least one of the two body rails 4 or the toothed rack 9. The electric drive device 6 is arranged stationary on one of the two body rails 4, and the toothed rack 9 is arranged on the drawer rail 5 of the guide device 3 for the continuous transmission of movement from a gear wheel 17 of the electric drive device 6 to the drawer rail 5. The electric drive device 6 and the power line 32 for the electric drive device 6 and for the lighting means 31 are arranged stationary on the guide device 3—on the body rail 4.

The movable furniture part 2 can be subjected to force via the electric drive device 6 via a control and/or regulating device 44 or a microcontroller 37, so that the connection to the body rail 4 has a dual function. The electric drive device 6 is designed to move the movable furniture part 2 at least in regions relative to the fixed furniture part 1, wherein the electric drive device 6 comprises the lighting means 31 arranged on the electric drive device 6 or the power line 32 of the electric drive device 6.

An exemplary method for illuminating a movable furniture part 2 (optionally the additional movable furniture part 42) can be explained as follows: The movable furniture part 2 is moved relative to the fixed furniture part 1 along the guide device 3 by the one electric drive device 6 in an automated manner, at least in some areas, and the lighting means 31 arranged on the electric drive device 6 or on the power line 32 of the electric drive device 6 is activated, so that the movable furniture part 2 is illuminated by the lighting means 31, wherein the movable furniture part 2 is moved and the lighting means 31 remains stationary. In particular, the additional movable furniture part 42 is illuminated by the lighting means 31 according to a movement of the first movable furniture part 41, wherein the lighting means 31 remains stationary on the electric drive device 6 of the first movable furniture part 41. For this purpose, the relative position of the additional movable furniture part 42 can be detected, wherein the lighting means 31 is activated via a control and/or regulating device 44 or the microcontroller 37 according to the determined relative position. For example, an algorithm or a computer program product can be stored in the control and/or regulating device 44 or the microcontroller 37, which comprises instructions which, when executed by a computing unit, cause the computing unit to execute the method from a memory unit which has a data connection with the computing unit.

Preferably, light is emitted in the visible wavelength range, wherein, for example, it can be provided that a wavelength range and/or an intensity of the lighting means 31 is changeable and/or adjustable—optionally via the electric drive device 6 or a receiving unit of the electric drive device 6 for configuring the electric drive device 6.

In general, a lighting means 31 can alternatively or additionally emit, for example, light in the infrared range for heating or light in the UV wavelength range—in particular UVC wavelength range—for sterilization or disinfection. In this way, stored goods or a surface can be freed from unwanted microorganisms or an interior of the movable furniture part 2 can be regulated to a desired temperature in order, for example, to be able to irradiate food—in particular in combination with a vacuum drawer and optionally so as to be adjustable—with varying intensity or adjustable wavelength range. Positioning on a stationary electric drive device 6 above the storage space is particularly suitable for this purpose. A locking device according to activation of the lighting means 31 is also conceivable.

In principle, introducing electricity into the movable furniture part 2 for power supply is complex and cumbersome, considering that the movement of the movable furniture part 2 must be taken into account. However, lighting of the movable furniture part 2 has the advantage of being able to clearly identify stored items in the movable furniture part 2—particularly in poor lighting conditions or at night. In particular, in the case of an electric drive device 6 arranged in a fixed position on the body rail 4, the introduction of current via the body rail 4 can also be used in a dual function to utilize power for supplying the lighting means 31 in a particularly advantageous manner.

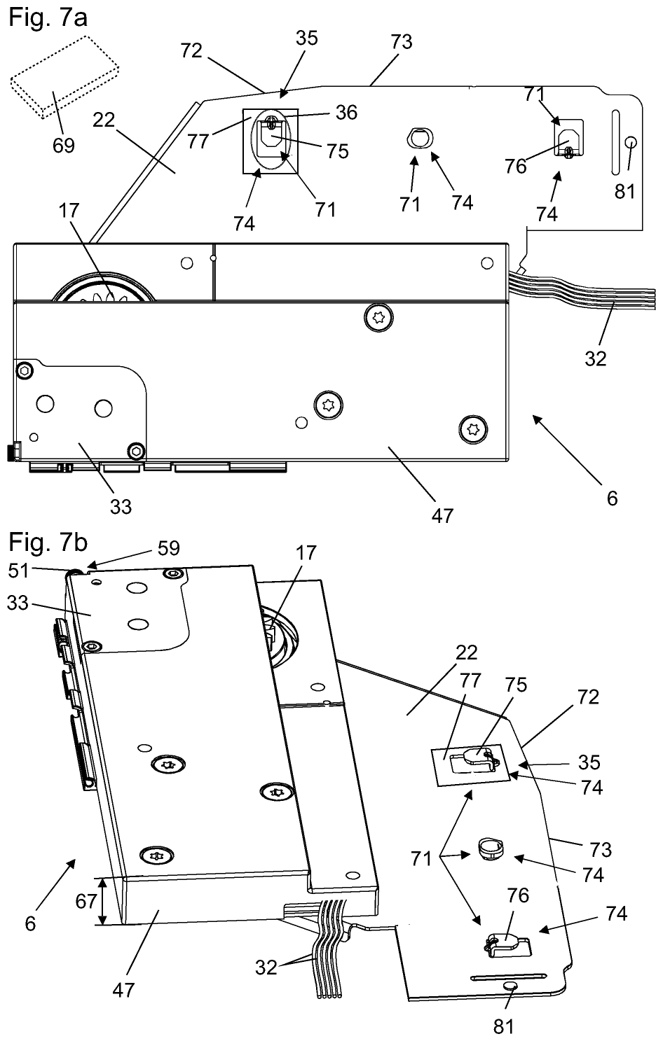

FIG. 7a shows an electric drive device 6 with the electric motor 7 which can be supplied with 230 V, wherein the electric drive device 6 comprises a plate-shaped support 22 for assembly on the body rail 4 of the guide device 3, wherein the support 22 comprises an inclined surface 72 which is such that the electric drive device 6 can be mounted on a body rail 4 arranged on the fixed furniture part 1 in the assembled state (cf. FIG. 6 in conjunction with FIG. 1b) in a collision-free manner via a pivoting process.

The electric drive device 6 has a longitudinal direction 27 and the inclined surface 72 of the support 22 is oriented at an acute angle between 5° and 30° relative to the longitudinal direction 27.

The inclined surface 72 for assembly on the body rail 4 is arranged on a free end 73 of the support 22 projecting transversely from the electric drive unit 6 and spatially spaced from the electric drive device 6 and the electric motor 7.

The electric drive device 6 comprises two coupling devices 74 on the support 22 for connection to a second intersection 35 of the body rail 4, although in general one coupling device 74 is sufficient. A coupling device 74 is in the form of a hook 75 punched and bent from a sheet metal, wherein an additional hook 76 is provided on the support 22 as a counter bearing for the connection of the electric drive device 6 to the body rail 4. For example, a carrier 36 for the closing device 8 or an ejection device 11 (optionally with tip-on function) can be arranged on the additional hook 76. The additional hook 76 can be used as a second intersection 35.

An additional coupling device 74 is present (analogous to the two coupling devices 74 as hook/additional hook 75, 76) as clip connection 71. The additional coupling device 74 is designed as a latching boss 81. The electric drive device 6 can be plugged translationally onto the body rail 4 via the latching boss 81 and the support 22 and can be securely fixed to the body rail 4 via the two hooks in a pivoting process, although in general a secure fixing can already be achieved via the latching boss 81.

During assembly, the latching boss 81 can elastically engage a corresponding recess for fixing purposes due to a recess provided in the material to the side. Between the hooks 75, 76, an extension is visible, which acts as a rotation axis for a rotational movement after translational contact. In general, fixation can also be provided, for example, by a latchable web via a purely translational movement in the sense of a clip connection.

The coupling device 72 in the form of the hook 75 overlaps with an opening 77 of the support 22. The opening 77 has a dual function in connection with a manufacturing process of the support 22, since the opening 77 can be used, for example, as a holding device (for example for handling or coating) in production. The opening 77 can in general be arranged alternatively or additionally on the body rail 4, although the dual function with regard to the connection and the manufacturing process can also be used here. The hook 75 projects through the opening 77 of the support 22 (or the body rail 4). The electric drive device 6 can in general be arranged indirectly via the support 22 on the body rail 4. The support 22 can consist of several parts. The hook 75 or the latching boss 81 can in general be arranged as a kinematic reversal on the body rail 4. The opening 77 or a multi-part structure of the support 22 is in general not required. Preferably, there is an opening 77 in the body rail 4 into which the hook 75 engages, wherein this opening 77 defines the position of the body rail 4 in a system for manufacturing the body rail 4. Another motion technology can be connected to the hook 74.

An exemplary method for retrofitting the electric drive device 6 to the guide device 3 in the installed state of the guide device 3 can be explained as follows. The electric drive device 6 for at least partially automated movement of the movable furniture part 2 is provided and the guide device 3 is mounted on the fixed furniture part 1 (see FIG. 1a) for guiding the movable furniture part 2 relative to the fixed furniture part 1, wherein, if necessary, an ejection device 11, a closing device 8, a carrier 36 for the ejection device 11 or a carrier 36 for the closing device 8 is removed from the guide device 3. Subsequently, the electric drive device 6 is arranged essentially completely (optionally with the furniture part front 23 projecting downwards) below the movable furniture part 2 to be moved at the second intersection 35 of the body rail 4 and the toothed rack 9 is arranged at the first intersection 34 of the drawer rail 5 for transmitting power from the electric drive device 6 to the drawer rail 5.

The first intersection 34 of the drawer rail 5 can in general be provided by a closing device 8.

At the second intersection 35, a locking device 69 (schematically indicated in dotted lines) for blocking a movement of the movable furniture part 2 relative to the fixed furniture part 1 and a carrier 36 for an ejection device 11 can be arranged. The carrier 36 for the closing device 8 provided in this embodiment is indicated in dotted line at the second intersection.

The inclined surface 72 reduces the risk of a collision with the fixed furniture part 1 or the body rail 4 during the assembly of the electric drive device 6 on the body rail 4, wherein the electric drive device 6 can be connected as an add-on to existing guide devices 3. The toothed rack 9 (or equivalent) can also be subsequently coupled to the drawer rail 9 to transmit movement from the electric drive device 6 to the movable furniture part 2. The intersections 34, 35 in conjunction with the components to be arranged thereon therefore has multi-function—on the one hand to ensure user-friendly retrofitting and on the other hand to connect a variety of flexibly interchangeable and varying movement technologies. This avoids the need for multiple intersections for a variety of motion technologies, while individual motion technologies can be easily connected as add-ons. Additional installation space for the assembly of the electric drive device 6 does not have to be provided, wherein the energy supply for the movable furniture part 2 and a sufficient transmission of movement to the movable furniture part 2 is also facilitated.

This is linked to a second aspect (linked via a synergy effect of the technical effects), which concerns a comfortable and (particularly in terms of available storage space) resource-saving attachment of the electric drive device 6, wherein—in particular via the connection to the body rail 4 and/or through an expedient gear design and/or selection of the electric motor 7—the electric drive device 6 can be located in a compact or narrow design below the movable furniture part 2. This allows the depth of the fixed furniture part 1 to be optimally utilized and a movable power supply is not required.

FIG. 7b differs from FIG. 7a only in that the electric drive device 6 is shown in a perspective view.

The electric motor 7 is arranged within a housing 47 with a thickness 67 in the vertical direction 15 in the position of use 14 of the assembly below 100 mm. It is possible to achieve thicknesses 67 below 80 mm. The thickness 67 is preferably below 60 mm (and is also conceivable below 40 mm), so that in conventional furniture a furniture part front 23 protrudes below the underside of the electric drive device 6.

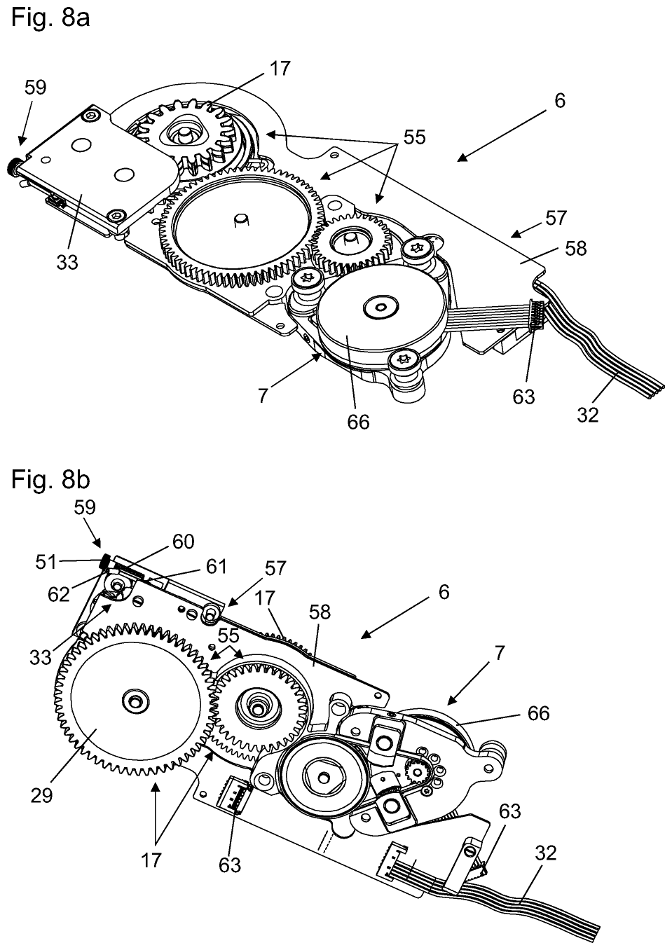

FIG. 8a shows that the electric motor 7 of the electric drive device 6 is in the form of a brushless external rotor motor 66, although in general it is also possible to provide brushed external rotor motors 66, disc rotor motors or rod motors. External rotor motors and disc rotor motors have a particularly flat design and are therefore preferred.

The electric motor 7 is connected to a plurality of gear stages 55 with gear wheels 17 for driving the movable furniture part 2. By configuring the gear stages 55, a thickness of 67 can be additional reduced and the other dimensions can also be made compact.

FIG. 8b differs from FIG. 8 only in that the components of the electric drive device 6 that are operatively connected to the electric motor 7 are viewed from a different angle.

The electric drive device 6 comprises a data interface 63 for the wired transmission of at least one digital data set stored in a memory unit, wherein the data interface 63 can in general be designed as an alternative or in addition to the radio signal-transmitting transmission of the digital data set.

The electric drive device 6 comprises a trigger sensor 59 for activating the electric motor 7 for a closed position of the movable furniture part 2, wherein the electric drive device 6 has a housing 47 which is disassembled in the illustration and the trigger sensor 59 is arranged on the housing 47 for contacting the movable furniture part 2 in the use position 14 of the electric drive device 6.

The trigger sensor 59 comprises a plunger 60 and a microswitch 61, which can be triggered tactilely and electronically via the microswitch 61. An exclusively electronically actuated trigger sensor 59 may be provided alternatively or in addition.

FIG. 9 shows a path measuring device 33 for the assembly, wherein the path measuring device 33 is designed to determine a position of the movable furniture part 2 relative to the fixed furniture part 1, and the position in the form of an absolute path traveled by the movable furniture part 2 relative to the fixed furniture part 1 can be clearly determined by the path measuring device 33.

The electric drive device 6 comprises an electric motor 7 which can be supplied with 230 V for the at least partially automated movement of the movable furniture part 2 relative to the fixed furniture part 1, wherein the path measuring device 33 is arranged on the electric drive device 6 or represents an integral component of the drive device 6 in interaction with the electric motor 7 and is integrated in the housing 47 of the electric drive device 6. However, an assembly within the housing 47 is not mandatory.

The movable furniture part 2 is translationally movable along the guide device 3 relative to the fixed furniture part 1 over the path 13 between the closed position and the open position 30 and can be driven over the entire path 13 by the electric drive device 6. The path measuring device 33 is provided for determining a position of the movable furniture part 2 relative to the fixed furniture part 1, wherein a relative position can be clearly determined via the path measuring device 33.

The path measuring device 33 comprises potentiometers 49 in the form of rotary potentiometers for determining the position, wherein Hall sensors (magnet in conjunction with Hall electronics) have proven to be particularly advantageous in the underlying electronics. Alternatively or additionally, a distance sensor 50—for example a distance laser—can be provided. The distance sensor system 50 can in general also be located spatially spaced from the electric drive device 6. The path measuring device 33 is arranged on the electric drive device 6.

The absolute path is determined starting from a predefined reference position, wherein the reference position is in the form of a relative position between the movable furniture part 2 and the fixed furniture part 1—in this embodiment given as stop 51 for the detection of an end position of the movable furniture part 2—or a reference position of the electric drive device 6—in this embodiment given as a starting position of the gear wheels 17 in connection with the electric motor 7.

A speed measuring device 52 is provided in the form of a potentiometer 49 arranged on the electric motor 7 or integrated in a control and/or regulating device 44 or a microcontroller 35. The speed measuring device 52 is used to determine a speed of the movable furniture part 2 relative to the fixed furniture part 1, wherein the movable furniture part 2 can be driven by the electric drive device 6 with a speed profile adapted to the determined speed of the movable furniture part 2 and/or the determined absolute path.

The control and/or regulating device 44 or the microcontroller 37 can be used to activate the electric motor 7 at a predefined speed determined by the speed measuring device 52, or at a predefined absolute path determined by the at least one path measuring device 33.

The position in the form of the absolute path traveled is stored as a dynamic data set and the speed as a dynamic data set for simulating the model via the computing unit of the microcontroller 37 or the control and/or regulation unit 44, at least temporarily in the memory unit.

The path measuring device 33 comprises a first position sensor 53 in the form of a sensor wheel designed as a gear wheel 17 and an additional position sensor 54 in the form of an additional sensor wheel designed as a gear wheel 17, wherein the absolute path can be clearly determined via a relative rotational position of the position sensors 53, 54.

The first position sensor 53 and the additional position sensor 54 are in the form of gear stages 55 of the electric drive device 6, wherein these gear stages 55 are not required for a transmission of the drive from the electric motor 7 to the drawer rail 5; for this purpose, additional gear stages 55 are used. A transmission ratio in the range between 1.01:1 and 1.2:1 that can be used for the path measuring device 33 can be transmitted via the first sensor wheel. A gear ratio in the range between 1.2:1 and 2.3:1 can be achieved between the first sensor wheel and the additional sensor wheel, and a gear ratio in the range between 1.5:1 and 2:1 can be achieved between the first sensor wheel and the additional sensor wheel.

The sensor wheels as position sensors 53, 54 are designed as gear wheels 17, which, however, are not required for the engagement of the electric drive device 6 in the toothed rack 9. The diameter 56 of the first sensor wheel differs from a diameter 56 of the second sensor wheel, wherein an absolute path of up to 1200 mm can be clearly determined by the path measuring device 33.

The absolute path of the movable furniture part 2 is determined starting from a reference position via a sum or a difference of rotation angles of the two position sensors 53, 54, so that a distancing between the movable furniture part 2 and the fixed furniture part 1 can be clearly calculated.

The path measuring device 33 comprises a magnetic bearing 57 over the housing 47 of the electric drive device 6 and a plastic part 58. The plastic part 58 acts as a dual function circuit board for a microcontroller 37.

The path measuring device 33 comprises a tactile trigger sensor 59 in the form of a plunger 60 and a microswitch 61, although in general it is also possible to provide other trigger sensors 59 which do not require mechanical triggering, so that a front gap between the movable furniture part 2 and the fixed furniture part 1 in the closed position for an overpressure movement for electronic triggering can be omitted, whereby a piece of furniture with a particularly aesthetically pleasing appearance can be achieved. A purely electronic triggering can be effected, for example, by contacting the movable furniture part 2, wherein, for example, a user pressing or wiping the movable furniture part on a furniture part front 23 is detected.

The path measuring device 33 is arranged together with the electric drive device 6 in a stationary manner on the body rail 4, wherein a movement transmission of the electric drive energy to the toothed rack 9 arranged on the drawer rail 5 takes place in order to be able to transmit force over the entire path 13 or starting from any point along the path 13 over a partial area of the path 13.

In the use position 14 of the assembly, the path measuring device 33 is arranged completely below the movable furniture part 2 indirectly via the electric drive device 6 on the body rail 4. If necessary, a furniture part front 23 of the movable furniture part 2 can protrude below the electric drive device 6 or the path measuring device 33 in order, for example, to contact the trigger sensor 59. However, at least one base of the movable furniture part 2 is arranged above the electric drive device 6.

Both gear wheels 17 for position or speed determination have a microchip. An additional gear wheel 17 transfers the energy of the electric motor 7 to the toothed rack 9.

The electric drive device 6 is arranged on the guide device 3 at least away from a closed position of the movable furniture part 2 without contacting the movable furniture part 2.

An exemplary method for moving the movable furniture part 2 relative to the furniture part 1 at least partially along the path 13 of the movable furniture part 2 between a closed position and a partial or complete open position 30 of the movable furniture part 2 by means of the electric drive device 6 and a path measuring device 33 is explained with reference to FIG. 10: Via the path measuring device 33, a position of the movable furniture part 2 relative to the fixed furniture part 1 is clearly determined as the absolute path traveled by the movable furniture part 2 relative to the fixed furniture part 1, and the movable furniture part 2 is moved translationally by the electric drive device 6 between the closed position and the open position 30 along the guide device 3 over a partial region of the path 13 according to the absolute path determined by the path measuring device 33. Driving the drawer rail 5 over the entire path 13 is in general possible due to the continuous coupling between the toothed rack 9 and the electric drive device 6, but is not mandatory.

According to this method, the absolute path can be clearly determined starting from a predefined reference position, via a relative position of the position sensors 53, 54 and starting from a reference position via a sum or difference of rotation angles of the position sensors 53, 54 as a distance between the movable furniture part 2 (in general the drawer rail 5) and the fixed furniture part 1 (in general the body rail 4).

Via a control and/or regulating device 44, or via a microcontroller 37, the movable furniture part 2 can be driven with a speed profile adapted to the determined speed or the determined absolute path, wherein the electric drive device 6 is activated at a predefined speed or at a predefined absolute path. For example, an algorithm or a computer program product may be stored which comprises commands which, when executed by a processing unit, cause the processing unit to execute the method from a memory unit which is connected to the processing unit in a data connection.

By means of the path measuring device 33 and in particular by means of the clearly definable relative position between the fixed furniture part 1 or body rail 4 and the movable furniture part 2 or drawer rail 5, it can be ensured that even after a power failure or other malfunction, the position of the movable furniture part 2 along the travel path 13 of the guide device 3 can be clearly determined. The absolute path traveled can be clearly calculated without reference travel, thus ensuring proper operation and, in particular, a drive that is adjusted to the position in a particularly fault-resistant manner.

In addition, the specific position can ensure proper detection of whether the movable furniture part 2 is to be subjected to force by the electric drive device 6 in the direction of the closed position or the open position 30. For example, based on the position and, if applicable, the speed, it can be determined whether the user of the movable furniture part 2 intends to move the movable furniture part 2 in a free-run area or intends to drive it in the closing direction or opening direction. In addition, a speed profile to be transmitted to the movable furniture part 2 can be adjusted so that an individual speed can be individually transmitted for each position along the guide device. The position can provide additional information as to whether the movable furniture part 2 is to be freely movable in the free-run area (possibly bidirectionally) or driven via the electric drive device (in the closing direction or opening direction), as well as to what extent the force is to be applied or with which speed profile the movable furniture part 2 is to be moved.

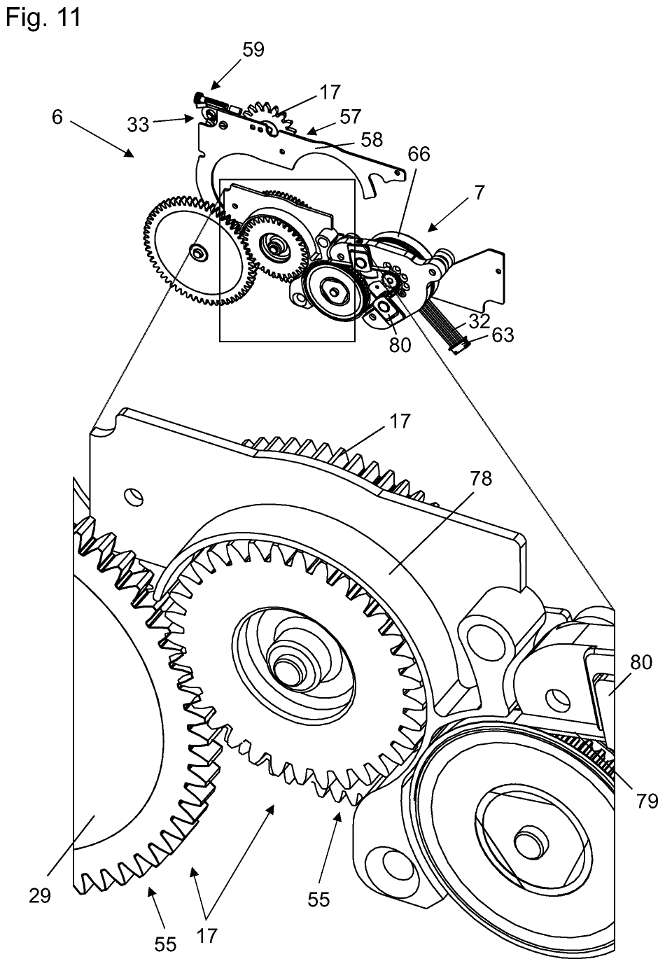

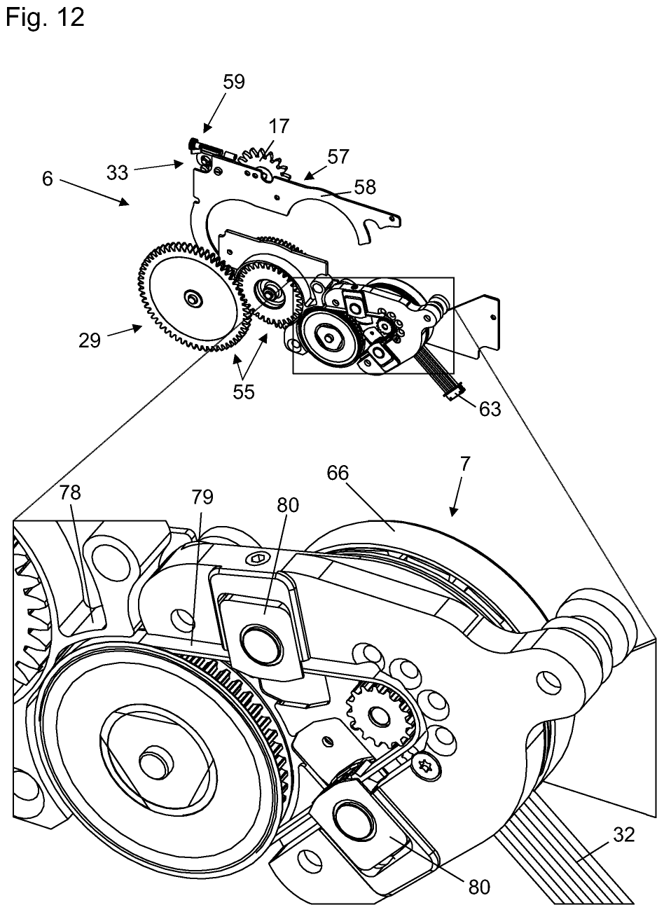

FIG. 11 and FIG. 12 show component parts of the electric drive device 6, wherein in FIG. 11, in the enlarged detail section, a protective body 78 integrated in the housing 47 can be seen, which protects the transmission—in particular a transmission stage 55—from abrasion by a belt (drive belt 79).

In FIG. 12, the belt drive in connection with the electric motor 7 is shown enlarged, wherein two belt tensioners 80 are provided, which provide a tension favorable for driving the electric drive device 6. In general, it is possible to provide only one belt tensioner 80 or several belt tensioners 80, although two belt tensioners 80 arranged on opposite sides of the drive belt 79 have proven to be particularly advantageous.

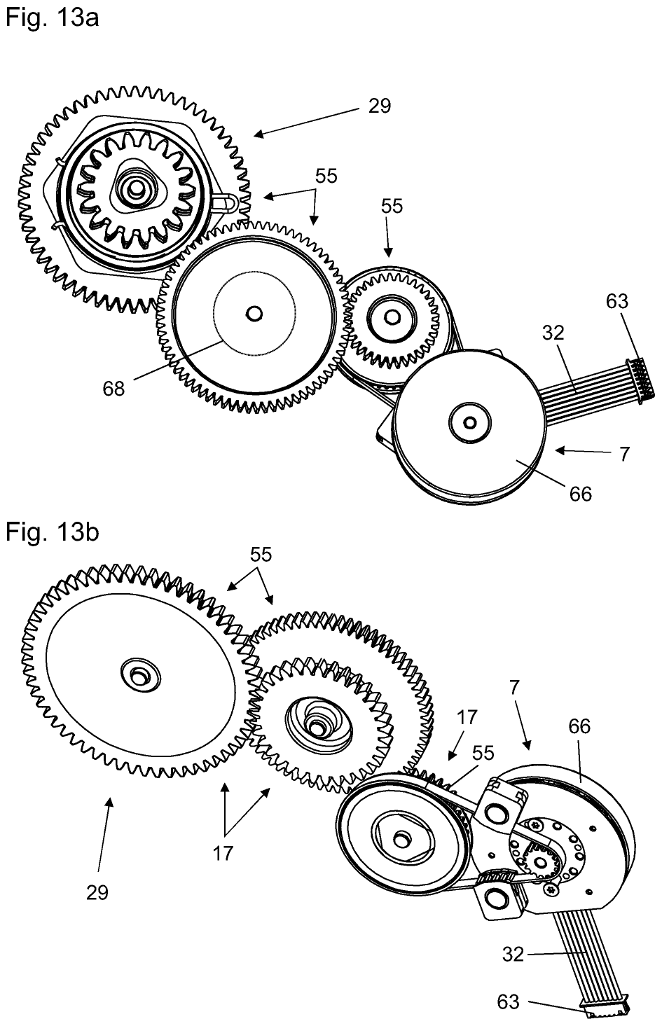

FIG. 13a shows the gear stages 55 of the electric motor 7, wherein the electric motor 7 is coupled to a one-way clutch 29.

The electric motor 7 can in general comprise an overload clutch 68, which is only indicated schematically by a dotted line, since this is not necessarily required as a separate component.

FIG. 13b differs from FIG. 13a only in that it is viewed from a different angle.

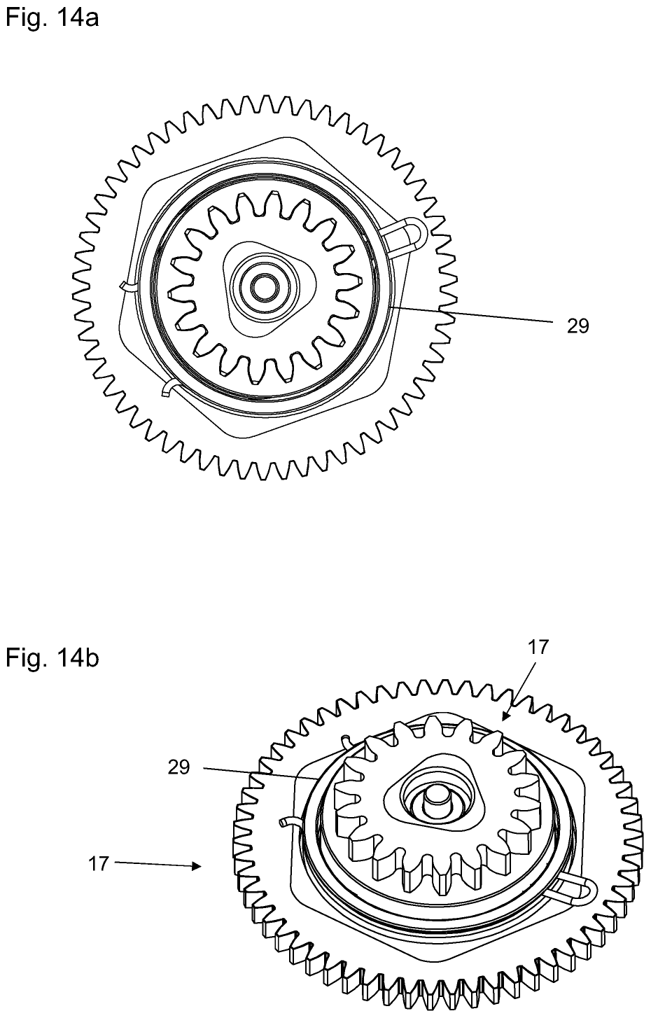

FIG. 14a and FIG. 14b show a one-way clutch 29 as a component comprising two gear wheels 17, which can act as gear stages 55. The one-way clutch 29 is in general not self-locking.

Technical details of such a one-way clutch 29—in particular a wrap spring one-way clutch—can be found in EP 2 086 372 B2.

Since the one-way clutch 29 is integrated in the electric drive device 6, the one-way clutch 29 can remain stationary on the body rail 4.

Specifically, the electric drive device 6 comprises the one-way clutch 29, with which the movable furniture part 2 can be decoupled from a drive via the electric motor 7 in the closing direction and in the opening direction—for example according to a speed of the movable furniture part 2 or a position of the movable furniture part 2—along the path 13. By means of the one-way clutch 29, the movable furniture part 2 can be moved between an open position 30 and a closed position—for example according to a force exerted on the movable furniture part 2—in a free-run area decoupled from a drive by the electric drive device 6 or can be driven over the path 13 (in general partial areas of the path 13) by the electric drive device 6.

An overload clutch 68 can in general also be provided, which—for example, according to a speed of the movable furniture part 2 or a position of the movable furniture part 2—enables a decoupling between the electric motor 7 and the toothed rack 9; by a double detachable connection of the toothed rack 9 (detachable connection between support device 10 and toothed rack 9 and closing device 8) during the engagement of the gear wheel 17 of the electric drive device 6 in the function as an overload clutch 68, an integrated overload clutch 68 can be dispensed with. In general, it may be sufficient that only the toothed rack 9 is detachably arranged on the support device 10 or only the support device 10 is detachably arranged on the closing device 8.

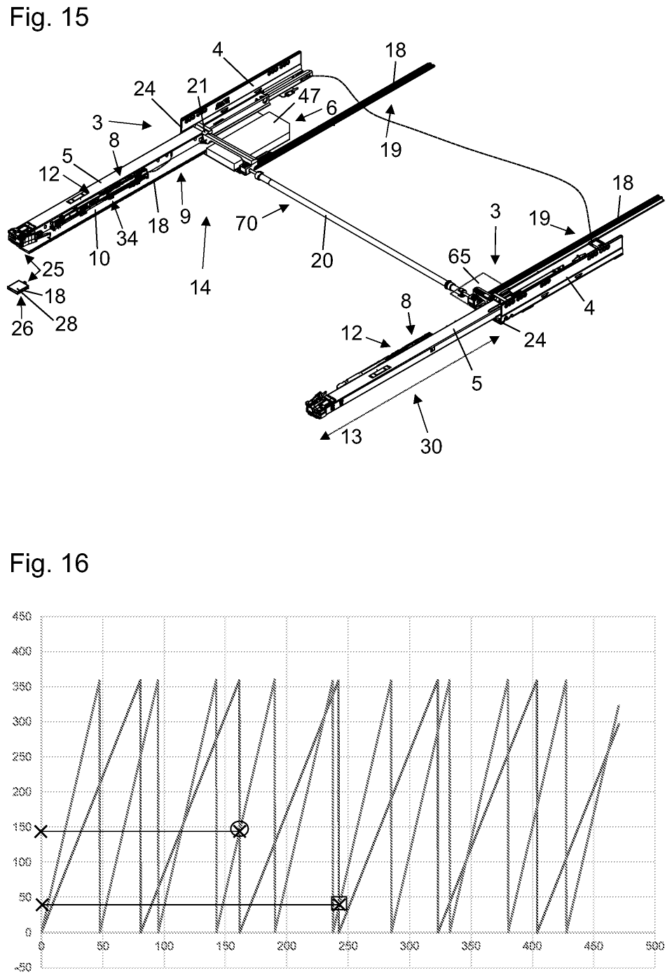

FIG. 15 shows an electric drive device 6 arranged on one side of the guide device 3, wherein an additional trigger sensor 65 (schematically indicated by dotted lines) for activating the electric motor 7 for a closed position (activation in or via the closed position or, if applicable, an overpressure position) of a movable furniture part 2 arranged on the fixed furniture part 1 is arranged stationary on the second furniture panel 64 via the body rail 4 arranged on the second furniture panel 64.

The additional trigger sensor 65 preferably comprises a damping device 12 or a buffer. The additional trigger sensor 65 can be in data communication with the electric drive device 6 via a radio connection or a cable connection. The additional trigger sensor 65 eliminates the need to machine the furniture part front 23. Preferably, the additional trigger sensor 65 is used together with the trigger sensor 59.

The assembly comprises a stabilization device 70 for lateral stabilization of the movable furniture part 2 along the guide device 3. In general, sufficient lateral stabilization can be generated via the movable furniture part 2 itself. It is conceivable to connect the stabilization device 70 to the second intersection 35 (see FIG. 7a).

Two additional toothed racks 19 are arranged on the guide device 3, which are arranged on the two body rails 4, wherein a synchronization rod 20 is arranged between the two additional toothed racks 19 for lateral stabilization on the two additional toothed racks 19. The toothing 18 of the additional toothed racks 19 is oriented upwards in the vertical direction 15 and is orthogonal to an orientation of the toothing of the toothed rack 9, although this is not mandatory.

The synchronization rod 20 with the two additional toothed racks 19 can be provided as a separate configuration as an add-on, wherein at least one of the three component parts can be connected to the second intersection 35, the toothed rack 9, the body rail 4 or the electric drive device 6.

There is a direct power connection between the two body rails 4 (schematically shown by a dashed line). A power line 32 for the electric motor 7 can be routed via the body rail 4 or the toothed rack 9—for example to supply energy to an ejection device 11.

On the left in the illustration it is schematically indicated that the toothed rack 9 can comprise a coupling device 25 with which the toothed rack 9 can be extended by a toothed rack extension 26, wherein the toothed rack 9 is then composed in the longitudinal direction 27 of at least two toothed rack segments 28. This makes it possible to provide a length-adjustable toothed rack 9 in order to be able to individually adjust the dimensions of the toothed rack 9 to the dimensions of the guide device 3 or to a pull-out path along the path 13. In general, it is also conceivable to design the toothed rack 9 to be telescopic.

FIG. 16 shows a diagram with sensor angles (in degrees) plotted on the ordinate and absolute paths along the path 13 (in mm) plotted on the abscissa. The position of the drawer rail 5 or the movable furniture part 2 can be clearly identified along the path 13 by the relative rotation position via the two position sensors 53, 54.

In the diagram, an intersection point of the sensor angles corresponding to a pull-out length of approximately 245 mm is marked with a square, wherein this intersection point corresponds to three complete rotations of the first position sensor 53 and five complete rotations of the second position sensor 54. The difference in the rotation angles corresponds to 36°, which clearly defines the position. An additional intersection point of the sensor angles corresponding to an absolute travel of approximately 165 mm is marked with a circle, this intersection point corresponding to two complete revolutions of the first position sensor 53 and five complete revolutions of the second position sensor 54. The difference in the rotation angles corresponds to 144°, which clearly defines the position.

In this embodiment, a signal tolerance of the first position sensor 53 based on a maximum number of six rotations for a clear position determination is equal to 60°. Analogously, a signal tolerance for the second position sensor 54 based on a maximum of 10 revolutions is equal to 36°. Combined, a tolerance can be reduced to +/−30° for the first position sensor 53 and +/−18° for the second position sensor 54, which is sufficiently accurate for a precise determination of the absolute travel via both position sensors 53, 54. For a given translation, a redundancy of intersection points for determining the absolute path may occur for long paths 13, wherein this undesirable situation can be eliminated by an entry in a memory unit or a varying translation. It is also conceivable to use additional sensors.

1. An assembly comprising:
a fixed furniture part, in particular a furniture body,
a furniture part, in particular a drawer, which is movable relative to the fixed furniture part,
a guide device, in particular a drawer pull-out guide, for guiding the movable furniture part relative to the fixed furniture part, with at least one body rail and at least one drawer rail displaceable relative to the at least one body rail, and
at least one electric drive device for at least partially automated movement of the movable furniture part relative to the fixed furniture part, comprising an electric motor, in particular one which can be supplied with 230 V,
wherein at least one closing device for the movable furniture part and at least one toothed rack operatively connected to the at least one electric drive device are provided, wherein the at least one closing device is arranged, preferably directly, on the at least one drawer rail, and the at least one toothed rack is arranged, preferably indirectly, on the at least one drawer rail, wherein the at least one toothed rack is detachably arranged on at least one support device, and/or the at least one support device is detachably arranged on the at least one closing device.

2. The assembly according to claim 1, wherein the at least one, preferably exactly one, support device is arranged at least in regions between the at least one toothed rack and the at least one closing device.

3. The assembly according to claim 1, wherein the at least one support device and/or the at least one closing device comprises at least one, preferably mechanical, ejection device and/or at least one damping device.

4. The assembly according to claim 1, wherein the at least one electric drive device is arranged in a stationary manner on the at least one body rail and is in constant connection to the at least one toothed rack for transmitting movement over an entire path for the movable furniture part along the guide device, and wherein it is preferably provided that the electric drive device comprises a gear wheel which meshes with the at least one toothed rack, particularly preferably in the use position of the assembly pointing upwards in the vertical direction or in the horizontal direction in the direction of the at least one drawer rail.

5. The assembly according to claim 1, wherein the at least one toothed rack is arranged at least in regions between the at least one electric drive device and the at least one drawer rail.

6. The assembly according to claim 1, wherein the guide device for moving the movable furniture part comprises two drawer rails arranged on two body rails, wherein exactly one electric drive device is arranged on one of the two body rails and/or exactly one toothed rack is arranged on one of the two drawer rails.

7. The assembly according to claim 1, wherein a power supply of the at least one electric drive device or of a possibly present additional current sink is guided via the at least one body rail and/or via the at least one toothed rack, preferably with a power connection between two body rails and/or two toothed racks.

8. The assembly according to claim 1, wherein a toothing of the at least one toothed rack in the use position of the assembly is oriented downwards in the vertical direction or in the horizontal direction in a direction pointing away from the at least one drawer rail, wherein it is preferably provided that the at least one toothed rack is coupled to a gear wheel of the at least one electric drive device, wherein
the at least one toothed rack with a vertically aligned toothing is mounted in the horizontal direction and/or in the vertical direction in the direction of the at least one drawer rail, particularly preferably relative to the at least one support device, so as to be pivotable or bendable about an imaginary axis and thus to be laterally and/or vertically movable to a limited extent, or
the at least one toothed rack with a vertically aligned toothing is mounted in the vertical direction downward and/or in the horizontal direction, particularly preferably relative to the at least one support device, so as to be pivotable or bendable about an imaginary axis and thus to be laterally and/or vertically movable to a limited extent.

9. The assembly according to claim 1, wherein the guide device comprises two body rails and two drawer rails which are displaceable relative to the body rails, wherein two additional toothed racks are provided which are arranged on the two body rails and/or the two drawer rails, wherein a synchronization rod is arranged between the two additional toothed racks for lateral stabilization on the two additional toothed racks.

10. The assembly according to claim 1, wherein at least one bearing device for the at least one toothed rack is arranged on the at least one drawer rail and the at least one toothed rack, wherein the at least one electric drive device, preferably a support for connecting the at least one electric drive device to the at least one body rail, can be traversed at least in regions by the at least one toothed rack and/or the at least one bearing device during a relative movement between the at least one drawer rail and the at least one body rail.

11. The assembly according to claim 1, wherein the movable furniture part in the use position of the assembly comprises a furniture part front, and the at least one electric drive device is arranged on the at least one body rail in the region of a free end of the body rail facing the furniture part front, preferably substantially flush with the free end.

12. The assembly according to claim 1, wherein the at least one toothed rack comprises a coupling device with which the at least one toothed rack can be extended by at least one toothed rack extension, wherein it is preferably provided that the at least one toothed rack is composed of at least two toothed rack segments in the longitudinal direction.

13. The assembly according to claim 1, wherein the assembly, preferably the at least one electric drive device, comprises at least one one-way clutch with which the movable furniture part can be decoupled from a drive via the electric motor in the closing direction and/or in the opening direction, preferably according to a speed of the movable furniture part and/or a position of the movable furniture part, along the path, wherein it is preferably provided that the movable furniture part can be moved between an open position and a closed position, particularly preferably according to a force exerted on the movable furniture part, in a free-run area decoupled from a drive by the at least one electric drive device and/or can be driven over the path by the at least one electric drive device.

14. The assembly according to claim 1, further comprising at least one lighting means, in particular stationary relative to the fixed furniture part, wherein the at least one lighting means is arranged on the at least one electric drive device and/or on a power line of the at least one electric drive device.

15. The assembly according to claim 1, further comprising at least one path measuring device for determining a position of the movable furniture part relative to the fixed furniture part, wherein the position can be determined, preferably unambiguously, in the form of an absolute path traveled by the movable furniture part relative to the fixed furniture part by the at least one path measuring device.

16. The assembly according to claim 1, wherein the guide device comprises at least one body rail arranged on the fixed furniture part and at least one drawer rail arranged on the movable furniture part, wherein the at least one drawer rail comprises at least one first intersection which is suitable for fixing an ejection device and/or the closing device to the at least one drawer rail, and the at least one body rail comprises at least one second intersection which is suitable for fixing a carrier for the ejection device and/or the closing device to the at least one body rail, wherein the at least one electric drive device is arranged or can be arranged on the at least one second intersection, and the at least one toothed rack for transmitting power from the at least one electric drive device to the at least one drawer rail is arranged or can be arranged on the at least one first intersection.

17. The assembly according to claim 1, wherein the at least one electric drive device is arranged in the use position of the assembly substantially completely below the movable furniture part on the at least one body rail.

18. The assembly according to claim 1, wherein the at least one electric drive device has a microcontroller comprising a computing unit and a memory unit which is or can be connected to the computing unit in data connection, wherein a model of the movable furniture part can be determined by the microcontroller according to at least one static data set stored in the memory unit, and/or a predicted movement trajectory of the movable furniture part along the guide device can be calculated according to at least one dynamic data set.
